(19) United States
(12) Patent Application Publication
(10) Pub. No.: US 2007/0030046 A1
(43) Pub. Date: Feb. 8, 2007

(54) Delay cell using a capacitor displacement current

(76) Inventors: Chung-Lung Pai, Hsinchu City (TW); Shih-Hui Chen, Kaohsiung City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/492,018

(22) Filed: Jul. 25, 2006

(30) Foreign Application Priority Data
Aug. 3, 2005 (TW) 094126392

(51) Int. Cl. H03H 11/26

(52) U.S. Cl. 327/290

(57) ABSTRACT

In a delay cell, a capacitor and a current mirror are configured to have an equivalent capacitance, and the current mirror establishes a capacitor displacement current to charge the capacitor, by which it is equivalently generated a much smaller current to charge the capacitor for a desired delay time. Therefore, the actual layout is much reduced in size for the capacitor, and the capacitor could be implemented within a chip.

### FIELD OF THE INVENTION

The present invention is related generally to a delay cell and, more particularly, to a delay cell using a capacitor displacement current.

### BACKGROUND OF THE INVENTION

Delay cell is often used in an integrated circuit to delay a signal for a time period. A simple delay cell comprises a current source and a capacitor. FIG. 1 shows a typical delay cell 10, in which current source 12 provides a source current I to node 14, capacitor C is connected to the node 14 to be charged to produce voltage V_{A} on the node 14, and switch SW is connected between the node 14 and ground GND to reset the voltage V_{A}. The voltage V_{A} is zero when the switch SW is on, and starts to rise up once the switch SW turns off. Therefore, the delay time ΔT can be determined by
C×V_{A}=I×ΔT, [EQ-1]
from which it is obtained the delay time

$$Δ T = \frac{C \times {V}_{A}}{I} . \qquad [ EQ \text{-} 2 ]$$

If a target voltage Vₜₐᵣ is set for the rising voltage V_{A} by a comparator, the delay time can be determined by

$$Δ T = \frac{C \times {V}_{tar}}{I} , \qquad [ EQ \text{-} 3 ]$$

from the time to release a reset via the switch SW to the voltage V_{A}. In practice, however, if the source current I supplied by the current source 12 is several microamperes, the capacitance of the capacitor C will be around one nF to obtain the delay time ΔT up to several milliseconds order. Thus it will consume large layout area on a chip. Conventionally, such delay cell is implemented by an extra pin on a chip to connect an external capacitor out of the chip. If the delay cell 10 is with the current source 12 of several nanoamperes, the capacitor C could be of pF order to obtain the delay time ΔT up to several milliseconds order. However, the junction leakage increases in high temperature, and thereby the current source 12 might not be able to support the source current I to the capacitor C if the leakage current is up to nA order.

Therefore, it is desired a delay cell implemented with small capacitor and not influenced by leakage.

### SUMMARY OF THE INVENTION

An object of the present invention is to provide a delay cell advantageous to integrated circuit.

Another object of the present invention is to provide a delay cell implemented with small capacitor.

Still another object of the present invention is to provide a delay cell operatable in high temperature.

According to the present invention, a delay cell comprises a capacitor displacement current to pass through a current mirror to equivalently generate a much smaller current to charge a capacitor. As a result, the equivalent capacitance increases significantly.

The actual layout is much reduced in size by the equivalent capacitance, and thereby the capacitor could be directly implemented within a chip.

### BRIEF DESCRIPTION OF THE DRAWINGS

These and other objects, features and advantages of the present invention will become apparent to those skilled in the art upon consideration of the following description of the preferred embodiments of the present invention taken in conjunction with the accompanying drawings, in which:

FIG. 1 shows a conventional delay cell;

FIG. 2 shows a first embodiment according to the present invention;

FIG. 3 is a simulation for the delay cell shown in FIG. 2;

FIG. 4 shows a second embodiment according to the present invention;

FIG. 5 is a simulation for the delay cell shown in FIG. 4;

FIG. 6 shows a third embodiment according to the present invention;

FIG. 7 is a simulation for the delay cell shown in FIG. 6;

FIG. 8 shows a fourth embodiment according to the present invention;

FIG. 9 shows a fifth embodiment according to the present invention;

FIG. 10 shows a sixth embodiment according to the present invention;

FIG. 11 shows a seventh embodiment according to the present invention; and

FIG. 12 shows an eighth embodiment according to the present invention.

### DETAIL DESCRIPTION OF THE INVENTION

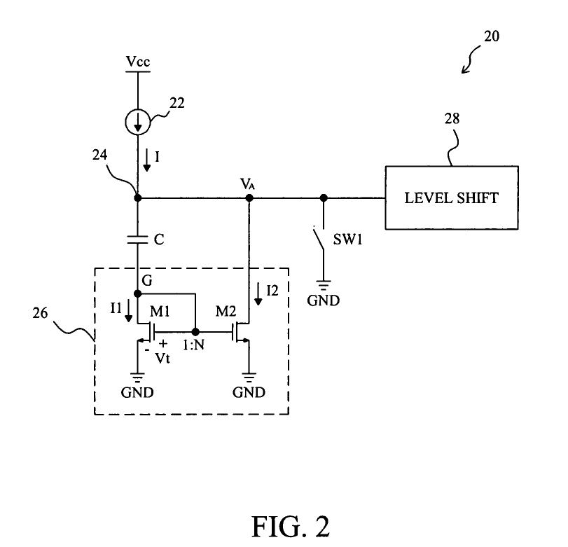

FIG. 2 shows a delay cell 20 according to the present invention, which comprises a current source 22 for supplying a source current I to node 24, capacitor C connected to the node 24, and a current mirror 26 having a reference branch to establish a capacitor displacement current I1 and a mirror branch to generate a mirror current I2 by mirroring the capacitor displacement current I1. Switch SW1 is further comprised between the node 24 and ground GND to reset the voltage V_{A}, and level shift unit 28 is connected to the node 24 to level shift the voltage V_{A}. When the switch SW1 turns on, the capacitor C is discharged, and once the switch SW1 turns off, the capacitor C is charged by the displacement current I1, causing the voltage V_{A} rising up.

According to Kirchhoff's Current Law, the source current
I=I1+I2. [EQ-4]
With the transistors M1 and M2 having the size ratio 1:N, it is obtained
I2=N×I1. [EQ-5]
In the delay cell 20, seen from the node 24, the capacitor C and the current mirror 26 are configured as an equivalent capacitor C_{eq}, thereby
C_{eq}×V_{A}=I×ΔT. [EQ-6]
Substituting the equations EQ-4 and EQ-5 into the equation EQ-6, it is obtained

$${C}_{eq} = \frac{( I 1 + I 2 ) \times Δ T}{{V}_{A}} = \frac{I 1 ( 1 + N ) \times Δ T}{{V}_{A}} . \qquad [ EQ \text{-} 7 ]$$

From the equation EQ-1, it is known that

$$C = \frac{I 1 \times Δ T}{{V}_{A}} . \qquad [ EQ \text{-} 8 ]$$

Based on the equations EQ-7 and EQ-8, it is concluded
C_{eq}=(1+N)×C. [EQ-9]
According to the equation EQ-6, it is determined the delay time

$$Δ T = \frac{{C}_{eq} \times {V}_{A}}{I} . \qquad [ EQ \text{-} 10 ]$$

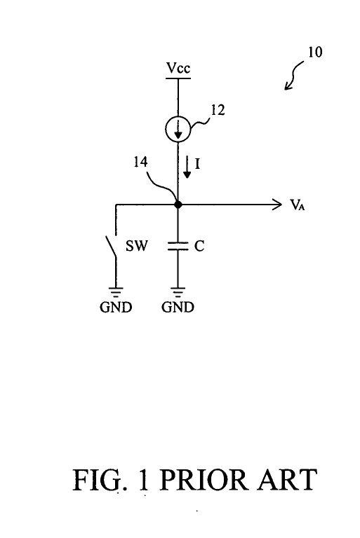

Since the mirror current I2 is proportional to the displacement current I1, whenever the displacement current I1 is established to flow through the capacitor C, the mirror current I2 will be proportionally generated and the voltage V_{A} will rise up accordingly. As shown in the equation EQ-9, the equivalent capacitance C_{eq} is (N+1) times of the capacitance C, and therefore, the delay cell 20 according to the present invention requires only a much smaller capacitance C for a same delay time ΔT as that produced by the conventionally delay cell 10 shown in FIG. 1. Namely, the layout area for the capacitor C is much reduced to

$$\frac{1}{N + 1}$$

times. In this case, with the current source 22 of several microamperes, only teen-times of pF is required for several milliseconds of the delay time ΔT, and therefore the capacitor C can be integrated within a chip. The delay cell 20 according to the present invention is thus pretty suitable for the circuits which need much greater delay time ΔT, for example in the range from hundreds of microseconds to several milliseconds.

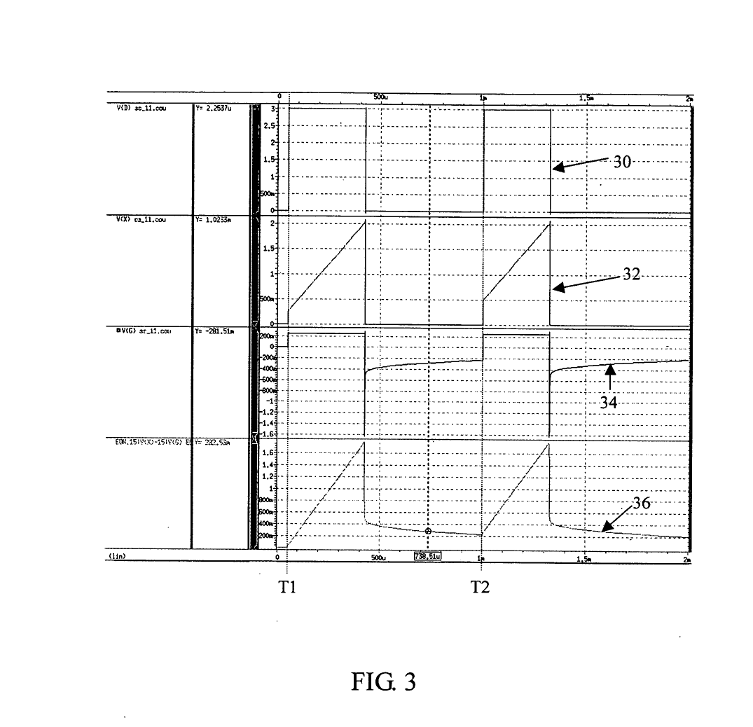

FIG. 3 is a simulation for the delay cell 20 shown in FIG. 2, in which waveform 30 represents the control signal for the switch SW1, waveform 32 represents the voltage V_{A}, waveform 34 represents the voltage on the node G, and waveform 36 represents the voltage difference V_{AG} across the capacitor C. In this embodiment, the switch SW1 turns off when the waveform 30 is at high level, and turns on when the waveform 30 is at low level. At time T1 in the beginning, the switch SW1 turns off, the voltage V_{A} starts to rise up, and due to the threshold voltage Vt of the transistor M1, the initial level of the voltage V_{A} is not zero, as shown by the waveform 32. At time T2, the switch SW1 turns off again so that the voltage V_{A} rises up again. However, in addition to the threshold voltage Vt, the body diode of the transistor M1 that prevents the charges on the node G from release to ground GND will push the initial level of the voltage V_{A} even higher, as shown by the waveform 32.

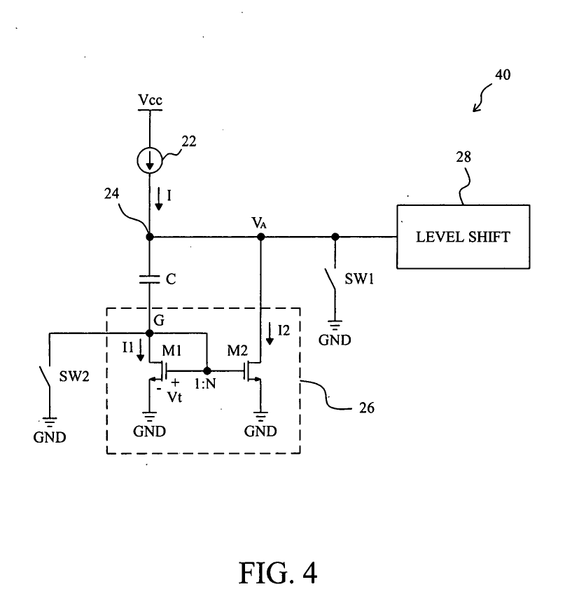

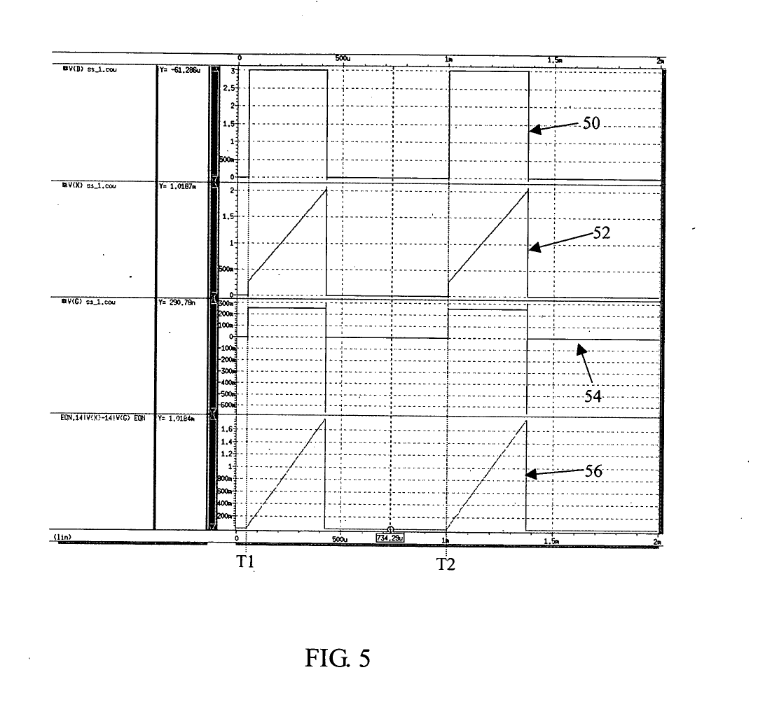

FIG. 4 shows a second embodiment according to the present invention. In addition to those elements shown in FIG. 2, delay cell 40 further comprises switch SW2 connected between the node G and ground GND to set the capacitor initial state. FIG. 5 is a simulation for the delay cell 40 shown in FIG. 4, in which waveform 50 represents the control signal for the switches SW1 and SW2, waveform 52 represents the voltage V_{A}, waveform 54 represents the voltage on the node G, and waveform 56 represents the voltage difference V_{AG} across the capacitor C. In this embodiment, the switches SW1 and SW2 both turn off when the waveform 50 is at high level, and turn on when the waveform 50 is at low level. When the switch SW2 turns on, the charges on the node G will release to ground GND, thereby setting the initial state of the voltage V_{A} at a same level each time it rises up, as shown by the waveform 52.

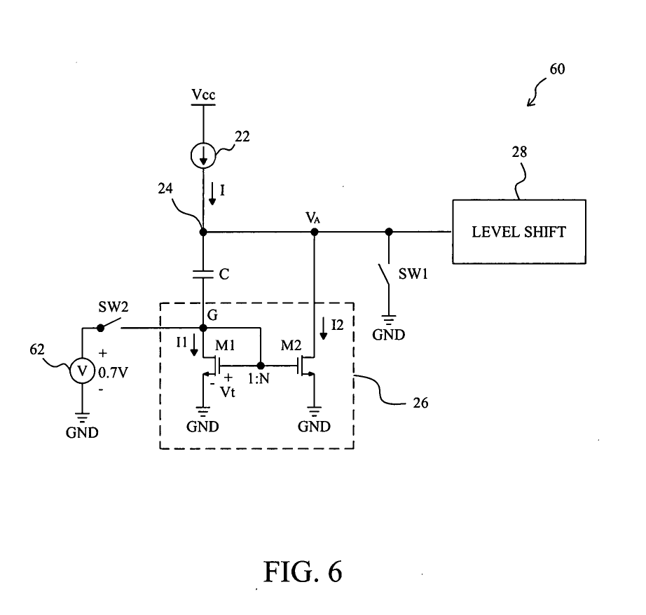

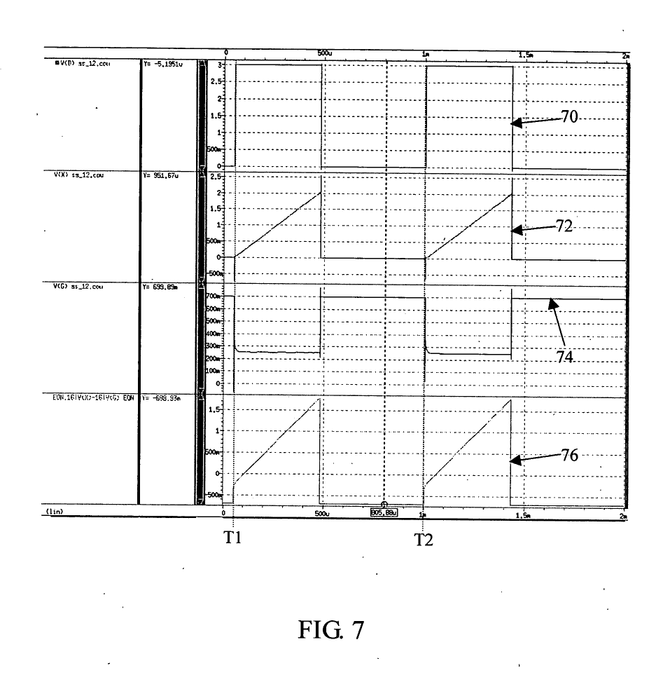

FIG. 6 shows a third embodiment according to the present invention. In addition to those elements shown in FIG. 4, delay cell 60 further comprises voltage source 62 inserted between the switch SW2 and ground GND to determine the capacitor initial state. FIG. 7 is a simulation for the delay cell 60 shown in FIG. 6, in which waveform 70 represents the control signal for the switches SW1 and SW2, waveform 72 represents the voltage V_{A}, waveform 74 represents the voltage on the node G, and waveform 76 represents the voltage difference V_{AG} across the capacitor C. In this embodiment, the switches SW1 and SW2 both turn off when the waveform 70 is at high level, and turn on when the waveform 70 is at low level. To compensate the offset resulted from the threshold voltage Vt of the transistor M1, the voltage source 62 is selected to have 0.7V such that the initial level of the voltage V_{A} is zero each time it rises up, as shown by the waveform 72.

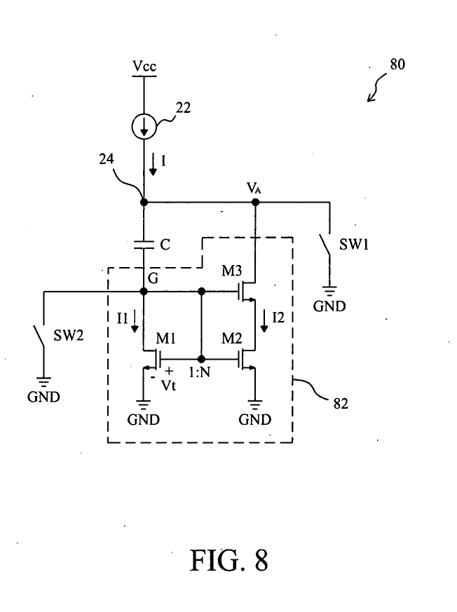

FIG. 8 shows a fourth embodiment according to the present invention, in which delay cell 80 uses cascode current mirror 82 having a reference branch connected to the capacitor C and a mirror branch connected to the node 24. The reference branch of the cascode current mirror 82 includes the transistor M1 to establish the displacement current I1, and the mirror branch of the cascode current mirror 82 includes serially connected transistors M2 and M3 to generate the mirror current I2 by mirroring the displacement current I1. In this embodiment, the operation also follows the equations EQ-9 and EQ-10.

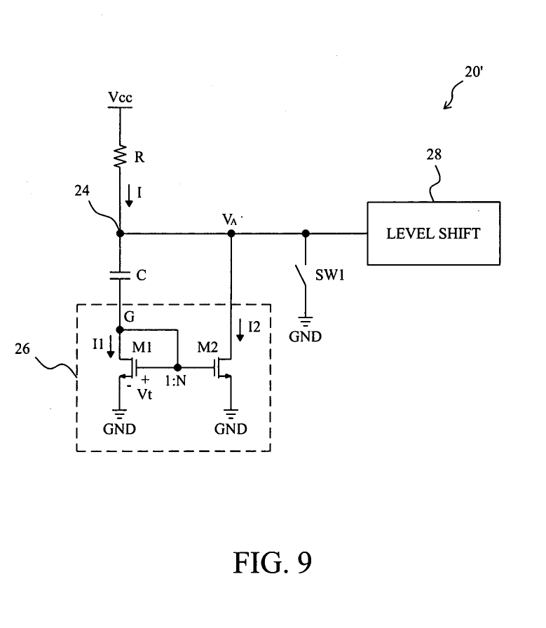

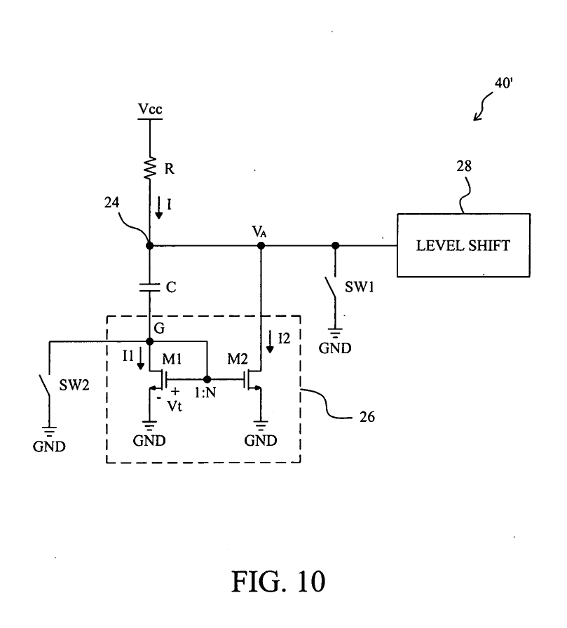

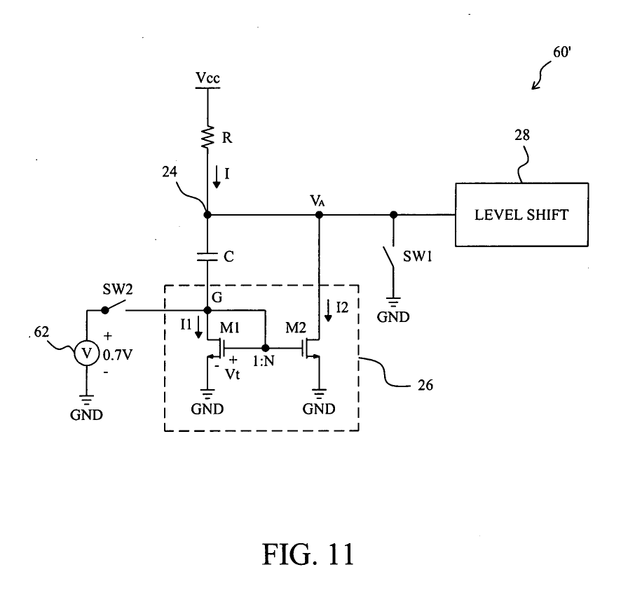

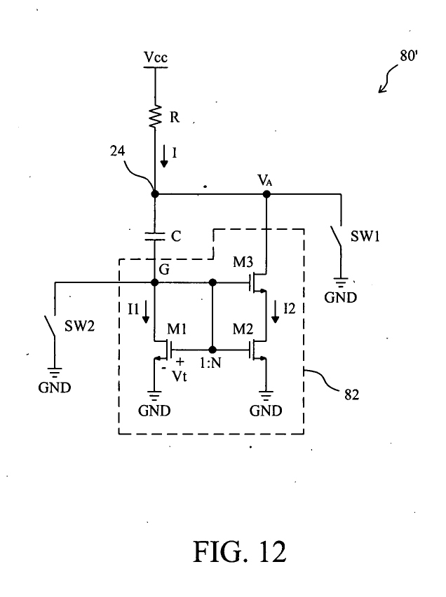

In the above embodiments, typically, the current source 22 may be implemented with biased MOS. However, resistor, such as implemented with MOS, could be used instead. For illustration, FIGS. 9-12 show the delay cells 20′, 40′, 60′ and 80′ which all have a resistor R connected between the supply voltage V_{cc} and the node 24 to provide the source current I.

While the invention has been described by way of example and in terms of the preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation to encompass all such modifications and similar arrangements.

What is claimed is:

1. A delay cell comprising:
a capacitor and a current mirror configured to have an equivalent capacitance, wherein the current mirror is configured to establish a capacitor displacement current and generate a mirror current from the capacitor displacement current; and
a current coupled to the capacitor and the current mirror through a node such that a voltage is produced on the node based upon the current and the equivalent capacitance.

2. The delay cell of claim 1, further comprising a switch connected to the node for resetting the voltage.

3. The delay cell of claim 1, further comprising a switch connected to the capacitor for setting a capacitor initial state.

4. The delay cell of claim 3, further comprising a supply voltage connected to the capacitor for determining the capacitor initial state.

5. The delay cell of claim 1, further comprising a level shift unit connected to the node for level shifting the voltage.

6. The delay cell of claim 1, wherein the current is provided by a biased MOS.

7. The delay cell of claim 1, wherein the current is provided by a resistor connected between a supply voltage and the node.

8. The delay cell of claim 1, wherein the current mirror is a cascode current mirror.
